(19) United States
(12) Patent Application Publication
(10) Pub. No.: US 2013/0098440 A1
(43) Pub. Date: Apr. 25, 2013

(54) PHOTOVOLTAIC CELL AND METHOD OF ITS MANUFACTURE

(71) Applicants: Gary Hodes, Rehovot (IL); Eran Edri, Rehovot (IL); Elena Rabinovich, Rehovot (IL)

(72) Inventors: Gary Hodes, Rehovot (IL); Eran Edri, Rehovot (IL); Elena Rabinovich, Rehovot (IL)

(73) Assignee: YEDA RESEARCH AND DEVELOPMENT CO. LTD., Rehovot (IL)

(21) Appl. No.: 13/807,597

(22) PCT Filed: Jun. 29, 2011
(86) PCT No.: PCT/IL11/00518

§ 371 Date: Dec. 28, 2012

Related U.S. Application Data
(60) Provisional application No. 61/359,532, filed on Jun. 29, 2010.

(51) Int. Cl. H01L 51/00; H01L 51/42

(52) U.S. Cl. CPC H01L 51/0002; H01L 51/4213
USPC 136/256; 438/82

(57) ABSTRACT

A method is presented for use in manufacture of a semiconductor device, such as a photovoltaic cell. The method comprises: providing a structure comprising a ZnO layer; applying a surface treatment to said structure for a certain time period to form a layer of ZnS on said ZnO layer; and depositing an active structure on said ZnS layer. The active structure may be a light absorbing structure, including a light absorbing semiconductor or a molecular light absorbing dye. The provision of the ZnS buffer layer between the ZnO layer and the active structure improves the device performance.

### FIELD OF THE INVENTION

This invention is generally in the field of integrated semiconductor devices, and relates to semiconductor devices configured for conversion of electromagnetic energy, such as a photovoltaic cell, in particular nanoporous solar cell, and a method for manufacturing such devices.

### REFERENCES

The following is a list of references relevant for the understanding of the background of the invention:

[1] CdSe-sensitized p-CuSCN/nanowire n-ZnO heterojunctions, Levy-Clement, C.; ft. Tena-Zaera; M. A. Ryan; A. Katty; C. Hodes Adv. Mater. 2005, 17, 1512-1515.

[2] Current-voltage characteristics and transport mechanism of solar cells based on ZnO nanorods/In₂S₃/CuSCN Dittrich, T.; Kieven, D.; Rusu, M.; Belaidi, A.; Tornow, J.; Schwarzburg, K.; Lux-Steiner, M. Appl. Phys. Lett. 2008, 93, 053113-3.

[3] Nanostructured solar cell based on spray pyrolysis deposited ZnO nanorod array, Krunks, M.; Katerski, A.; Dedova, T.; Oja Acik, I.; Mere, A. Sol. Energy Mater. Sol. Cells. 2008, 92, 1016-1019.

[4] Understanding the factors that govern the deposition and morphology of thin films of ZnO from aqueous solution, Govender, K.; Boyle, D. S.; Kenway, P. B.; O'Brien, P. J. Mater. Chem. 2004-14, 2575-2591.

[5] Fabrication of ZnO/CdS core/shell nanowire arrays for efficient solar energy conversion Tak, Y.; Hong, S. J.; Lee, J. S.; Yong, K. J. Mater. Chem. 2009, 19, 5945-5951.

[6] Solution-based synthesis of a CJS nanoparticie/ZnO nanowire heterostructure array, Tak, Y.; Hong, S. J.; Lee, J. S.; Yong, K. Cryst. Growth Des. 2009, 9, 2627-2632.

[7] Nanocrystal Layer Deposition: Surface-Mediated Templating of Cadmium Sulfide Nanocrystals on Zinc Oxide Architecture, Spoerke, E. D.; Lloyd, M. T.; Lee, Y.; Lambert, T. N.; McKenzie, B. B.; Jiang, Y.; Olson, D. C.; Sounart, T. L.; Hsu, J. W. P.; Voigt, J. A. J. Phys, Chem. C 2009, 113, 16329-16336.

[8] Double-Sided CdS and CdSe Quantum Dot Co-Sensitized ZnO Nanowire Arrays for Photoelectrochemical Hydrogen Generation Wang, G,; Yang, X.; Qian, F,; Zhang, J. Z.; Li, Y. Nano Lett. 2010, 10, 1088-1092.

[9] Chemical bath deposition of CdS quantum dots on vertically aligned ZnO nartorods for quantum dots-sensitized solar cells, Lee, W.; Min, S. K.; Dhas, V.; Ogale, S. B.; Han, S. Eleetrochem. Commun. 2009, 11, 103-106.

[10] Comparison of dye- and semiconductor-sensitized porous nanocrys liquid junction solar cells, Hodes, G. J. Phys. Chem. C 2008, 112, 17778-17787.

[11] High-efficiency Cu(In,Ga)Se₂ thin-film solar cells with a CBD-ZnS buffer layer, T. Nakada, M. Mizutani, Y. Hagtwara and A. Kunioka, Sol. Ener, Mater. Sol. Cells, 67, 255-260 (2001).

[12] Method of the application of a zinc sulfide buffer layer on a semiconductor substrate, U.S. Pat. No. 7,704,863.

[13] Reliable chemical bath deposition of ZnO films with controllable is morphology from ethanolamine-based solutions using KMnO₄ substrate activation, Kokotov, M., Hodes, G. J. Mater. Chem., 2009, 19, 3847-3854.

[14] A Solid-State Dye-Sensitized Solar Cell Fabricated with Pressure-Treated P25-TiO₂ and CuSCN: Analysis of Pore Filling and IV Characteristics, O'Regan, B.; Lenzrnann, F.; Muis, R.; Wienke, J. Chem. Mater, 2002, 14, 5023-5029.

### BACKGROUND OF THE INVENTION

Nanoporous solar cells are usually based on high surface area metal oxides as (most commonly) electron conductors, on which a solar-absorbing material is deposited, followed by deposition of a hole-conducting phase. The solar-absorbing material is commonly a molecular dye, as in a dye sensitized solar cell (DSC), but can also be a semiconductor as in a semiconductor-sensitized solar (SSSC). The hole-conducting phase can be a liquid electrolyte or a solid hole-conductor.

ZnO nanorod films and nanoporous TiO₂ are known to be suitable for use as the electron conductor in semiconductor-sensitized nanoporous solar cells (SSSCs). While the most common oxide used is nanoporous TiO₂, ZnO is being increasingly investigated, and has shown recent success in solid state SSSCs (or Extremely Thin Absorber—ETA—cells) [1-3]. The common (and most thermodynamically stable) crystallographic wurtzite structure of ZnO has hexagonally close-packed lattice structure, where the oxygen and zinc ions are both tetrahedrally coordinated and their planes are alternately packed. This, on a larger length scale, develops to the anisotropic, rod-like structure that commonly forms when ZnO is deposited by certain techniques, especially CBD [4].

### General Description

There is a need in the art for a novel technique suitable for manufacturing semiconductor devices, in particular those for electromagnetic energy conversion or photovoltaic cells, such as semiconductor sensitized solar cells (SSSC) or dye sensitized solar cells (DSSCs).

The DSSC and SSSC cells are similar in concept: A light absorbing material deposited or adsorbed onto a transparent, porous material (usually an oxide), with a hole conducting phase forming a second junction to the light absorber. The main difference is that in the DSSC, the absorber is a molecular dye, while in the SSSC cell, it is a solid semiconductor. The SSSC is often further sub-divided into cells with a liquid or solid hole conductor: The latter is known as an ETA cell.

As indicated above, ZnO nanorod films are increasingly used as an electron conducting material in SSSCs. Such electron conducting material is located on an electrically conductive substrate forming an optically transparent electrode structure of the photovoltaic cell, by which it is exposed (at the substrate side) to external electromagnetic radiation. In the conventional configuration, this electron conducting material is coated, often using chemical bath deposition (CBD), by a light absorbing semiconductor layer, typically of metal chaicogenides (common examples being CdS, CdSe and Sb₂S₃).

In DSSCs, TiO₂ is much more commonly used than ZnO. This is primarily because of a difficulty in finding a suitable dye, both from the point of view of adsorption onto the ZnO and corrosion of ZnO.

The nanorod morphology of ZnO [4] increases the surface area of a ZnO film by typically 10 to some tens of times, as compared to a planar film, depending on nanorod diameter, length and spacing. This feature makes ZnO suitable for nanoporous cells, and particularly for SSSCs, where the semiconductor thickness can be considerably thicker (typically several tens am) compared to the molecular thickness in a DSC, which requires a much larger surface-area enhancement.

The inventors have found that some of the known techniques for manufacture of photovoltaic cells of the kind specified limit the performance of the cell mainly due to the morphology of the semiconductor light absorbing layer on the ZnO layer. Direct deposition of light absorbing semiconductor layers in many techniques tends to form clusters of the semiconductor. These clusters result in poor coverage and reduce the performance of the solar cell. This is because clustering of the light absorber crystals increases the chances of electron-hole recombination [10] and also promotes direct contact between the hole and electron conductors (which might be problematic).

Ideally, the semiconductor coating, when deposited on the ZnO nanorod layer, should be as conformal and uniform as possible in order to exploit the surface of the ZnO layer, to minimize the local thickness of the semiconductor coating and to prevent direct contact between the electron conducting layer and a hole-conducting layer. In this connection, it should be understood that the term layer used herein refers to both a continuous material layer and a patterned layer, e.g. formed by a porous material or dispersed particles (crystals). Thus, for example, the ZnO nanorod film provides a layer of porous structure.

One frequently-used material deposition technique, based on Successive Ionic Layer Adsorption and Reaction (SILAR) method, utilizes multiple sequential dipping of a substrate in a solution of Cd ions and Na₂S solution, resulting in full coverage of the surface but with small crystallites of CdS [5]. Another known technique based on the use of chemical bath deposition (CBD) [4] to form semiconductor light absorbers on ZnO, usually results in the formation of poorly-covering deposits of isolated clusters, in particular when the commonly-used thiourea/ammonia bath for CdS is employed 16]. In ref. [6], apparently good coverage could be obtained using very dilute deposition solutions, but in this case, the amount of CdS deposited was very small, as seen by the absorbance spectrum. The use of a thioacetamide (probably neutral or slightly acidic) bath for CdS is described in some literature as giving good coverage of the ZnO nanorods [7], while in some other literature is described as resulting in heterogeneous cluster coverage [8]. An unusual non-aqueous bath (almost all CBD baths are aqueous) using thiourea was also found to give good coverage [9].

The inventors have found that a relatively simple pretreatment of the ZnO nanorod film (typically on a substrate) provides for improving the operation of the semiconductor device. There are a number of reasons for this improvement. One clearly visible reason is that the treatment significantly improves the homogeneity (and overall coverage) of the subsequently-deposited semiconductor on the ZnO. Other likely reasons are that it causes healing of cracks/pinholes in the dense oxide layer required in an ETA cell and reduction of electron-hole recombination by forming a buffer layer on the ZnO. In the case of DSSC to devices, it may also provide for better adsorption of dye as well as prevention of ZnO corrosion.

This pretreatment includes a surface treatment of a ZnO layer (typically a thin, nanorod film) aimed at converting the surface of the ZnO nanorods to a thin layer of ZnS. Thus, the ZnS layer serves as an intermediate layer for further creation of a semiconductor (fight absorbing) layer. This surface treatment and the resulting relatively conformal semiconductor layer enhance the solar cell efficiency.

ZnS (and various mixed stoichiotrietries of Zn(OH)S) has been studied for use as a buffer layer on semiconductor surfaces for use in thin film structures [11, 12]. According to these techniques, the films are almost invariably deposited by chemical bath deposition involving immersion of the substrate in a solution of Zn ions, a source of sulfur (usually thiourea and complexant for the Zn ions (usually ammonia).

According to one aspect of the present invention, there is thus provided a method for use in manufacturing a semiconductor device, in particular an electrode arrangement for a photovoltaic cell. The method comprises: providing a structure comprising an electron conductive layer, such as ZnO (e.g. on a substrate, e.g. an electrically conductive and/or optically transparent substrate); applying a surface treatment to said electron conductive layer (by conversion of ZnO to ZnS by either a solution or gas phase reaction) and depositing an active structure (material composition forming an active element of the device) on the treated surf ice.

In some embodiments, the active material composition is a semiconductor structure and may be light absorbing. The semiconductor structure may comprise a light absorbing semiconductor which also acts as a hole conductor, such as P3HT (poiyhexathiophene) or CuInS₂ or Cu_{R}S,: or may comprise a light absorbing semiconductor and a layer of hole-conductive material (which may be solid or liquid) on top of the light-absorbing layer. Examples of such hole conducting materials are CuSCN, P3HT, NiO (nickel oxide), PEDOT:PSS (poly 3,4-ethylene dioxythiophene)poly(styrenesulfonate), spiro OMeTAD. In yet other embodiments, the active material composition comprises a light absorbing molecular dye and a hole-conductive material (solid or liquid).

As indicated above, the ZnO layer may be a continuous material layer, a patter layer (e.g. porous material), or may be in the form of dispersed particles (crystals).

More specifically, and especially considering the semiconductor device configured for use as a photovoltaic cells, the method comprises: providing a structure formed by a ZnO layer on an electrically conductive and optically transparent substrate; applying a surface treatment to said structure for a certain time period to form a layer of ZnS on said ZnO layer; and depositing an active structure on said ZnS layer, the active material composition comprising either one or more semiconductor layers including a light absorbing layer, or a molecular dye layer structure.

As indicated above, the surface treatment resulting in formation of the ZnS buffer layer between the ZnO layer and the active material composition provides for a substantially even coating of the ZnO layer by said active material composition.

Similarly, in some embodiments, deposition of a hole-conductor layer on top of the light absorbing semiconductor may be used.

As indicated above, in the field of photovoltaic cells, the optically transparent electrode is ⁻typically constructed from a layer of ZnO film on an electrically conductive substrate (conducting glass). The common (and most thermodynamically stable) crystallographic wurtzite structure of ZnO has a hexagonally close-packed lattice structure. This structure, on a large length scale, develops an anisotropic, rod like structure when ZnO is deposited by certain techniques including CBD. This nanorod morphology increases the surface area of the ZnO film by typically 10 to some tens of times as compared to a planar film. This feature makes ZnO a suitable candidate for nanoporous cells,and particularly for SSSCs.

Among the semiconductors deposited on ZnO, metal chalcogenides (S, Sc, Te, or oxides thereof) are typically considered, and especially CdS and CdSe which are among the most commonly used. Depositing CdS or CdSe using CBD technique on a ZnO layer was found to result in poor coverage with clusters of the semiconductor light absorbers.

According to the present invention, a surface treatment of the nanorod ZnO film dramatically improves the coverage of the CdS or CdSe light absorbing layer, and thus the performance of the solar cell. The surface treatment according to the present invention aims to at converting the surface of the ZnO layer to a thin surface layer of ZnS. This is done, according to an embodiment of the present invention, by an alkaline sulfide solution treatment containing sulfide ions (e.g. S⁻² ions). Such alkaline sulfide solution can be, for example an aqueous solution of Na₂S.

The light absorbing layer, of CdS or CdSe, deposited on surface-treated ZnO nanorod films by CBD was found to produce a uniform, relatively conformal coating for layer thicknesses of up to at least tens of nanometers.

A hole-conducting layer may be deposited on top of the light-absorbing layer. The hole-conducting layer can be formed, for example, by a layer of CuSCN, but other hole-conductive materials can be used.

Thus, according to another aspect of the invention, there is provided a method for use in manufacture of a semiconductor device, the method comprising: providing a structure comprising a ZnO layer; applying a surface treatment to said structure for a certain time period to form a layer of ZnS on said ZnO layer; and depositing a semiconductor substance on said ZnS layer.

According to yet another aspect of the present invention, there is provided a method for manufacturing an electrode arrangement for a photovoltaic cell, the method comprising: providing a structure formed by a ZnO layer (e.g. on an optically transparent substrate); fabricating a light absorbing semiconductor (e.g. CdS or CdSe) layer between said structure and a hole conducting layer of the photovoltaic cell. The fabrication comprises applying a surface treatment to the ZnO structure to form a support layer of ZnS in between ZnO layer and said light absorbing semiconductor (e.g. CdS or CdSe) layer.

The support layer optimizes the uniformity of coating of the ZnO layer by the semiconductor layer structure (e.g. CdS or CdSe layer).

According to a yet further aspect of the invention, there is provided a semiconductor device, such as a photovoltaic cell for example, the device comprising: a ZnO pocous layer (e.g. on a substrate), a ZnS layer on said ZnO layer, and an active structure on said ZnS layer, said active structure comprising one of the following: (a) a semiconductor structure comprising a light absorbing semiconductor; and (b) a light absorbing molecular dye structure.

The semiconductor layer structure may be in the form of a single semiconductor layer acting as a hole conductor, or it may be a two-layer structure formed by a hole conducting layer on top of a semiconductor layer.

The light absorbing layer may be of a thickness of about 10-50 nm or less, depending on the structure.

### BRIEF DESCRIPTION OF THE DRAWINGS

In order to understand the invention and to see how it may be carried out in practice, embodiments will now be described, by way of non-limiting example only, with reference to the accompanying drawings, in which;

FIGS. 1A and 1B illustrate two examples, respectively of a semiconductor device according to the invention. e.g., suitable for use as photovoltaic cell;

FIG. 2 is a graph showing the performance of photovoltaic solar cells, comparing that of the conventionally configured cell and the cell according to the invention;

FIGS. 3A to 3D show SEM images comparing the conventional and the invented techniques for manufacture of an electrode arrangement for a photovoltaic cell: FIG. 3A shows ZnO nanorods; FIG. 3B shows sulfide-treated ZnO; FIG. 3C shows CdS deposited on untreated ZnO, FIG. 3D shows CdS deposited on treated ZnO; insets show higher magnification images (C and D) using backscattered images to increase the contrast between the light atomic weight ZnO (dark) and heavier CdS (light). In the inset of FIG. 3D a region where CdS has been partially peeled off was deliberately chosen to show a difference between ZnO and CdS.

FIGS. 4A to 4F are SEM images showing the effect of sulfide treatment on ZnO surface coverage by CdS from ammonia/thiourea bath (FIGS. 4A and 4B), the effect of sulfide treatment on ZnO surface coverage by CdS from a thioacetamide bath (FIGS. 4C and 4D), the effect of sulfide treatment on ZnO surface coverage by CdSe from CBD (FIGS. 4E and 4F). Where FIGS. 4A, 4C and 4E correspond to nontreated ZnO rods and FIGS. 4B, 4D and 4F correspond to sulfide-treated ZnO rods, and the insets are higher magnification backscattered to images; scale bars for the insets are all 0.5 μm.

FIGS. 5A and 5B show CBD CdS on top of untreated electrodeposited ZnO (FIG. 5A) and CBD CdS on top of treated electrodeposited ZnO (FIG. 5B).

FIG. 6 shows cross-section SEM images of ZnO treated for various times with a S solution.

FIG. 7 shows SEM images illustrating how the electrode manufacture results depend on both the surface treatment duration and the CdS layer deposition duration for short CdS deposition times.

### DETAILED DESCRIPTION OF EMBODIMENTS

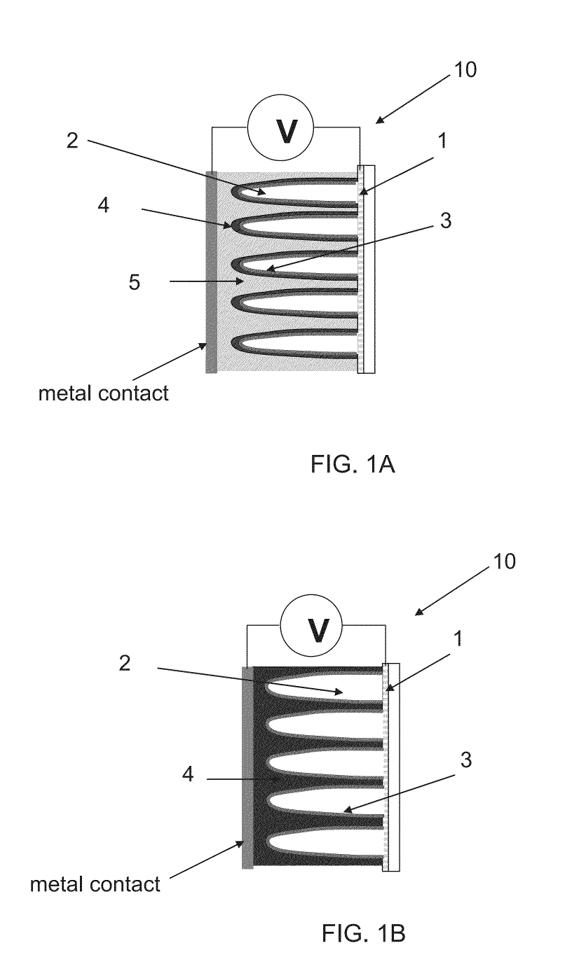

Reference is made to FIGS. 1A and 1B showing schematically two examples of a semiconductor device of the present invention. In these specific but not limiting examples, the semiconductor device, generally designated 10, is configured as a semiconductor photovoltaic cell, such as DSSC and SSSC, utilizing a ZnO nanorod layer. The structure of a photovoltaic cell of the present invention is distinguished from the conventional configurations in that it includes a converted surface layer to allow even deposition of a semiconductor thereon (light absorbing semiconductor in the present examples).

As shown in FIG. 1A, the semiconductor device 10 (or basic solar cell unit) includes an electrically conducting substrate 1 (which is also optically transparent, e.g. conducting glass, considering photovoltaic cell embodiment of the device), an electron conducting layer 2 (typically porous oxide, such as ZnO nanorod layer) on said substrate 1, and a semiconductor layer 4 (light absorbing semiconductor layer). Further provided is a hole-conducting layer 5 on top of the semiconductor layer 4. The hole-conducting layer 5 may be a liquid electrolyte or a solid hole-conductor.

According to the invention, the device also comprises a (thin) ZnS surface layer 3 between the ZnO and (light absorbing) semiconductor layers 2 and 4. As will be described more specifically further below, the ZnS layer 3 is formed by surface treatment of the ZnO layer.

It should be noted that an example of FIG. 1A may correspond to the use of the invention for DSSCs configuration. Considering the DSSC-based semiconductor device, the to active material composition includes a molecular dye structure. Hence, layer 4 is a light absorbing molecular dye.

The semiconductor device 10 of FIG. 1B is configured generally similar to that of FIG. 1A but has no additional hole-conducting layer on top of semiconductor 4. Here, the (light absorbing) semiconductor 4 itself acts as a hole conductor. This may be, for example, P3HT (polyhexathiophene), or CuInS₂.

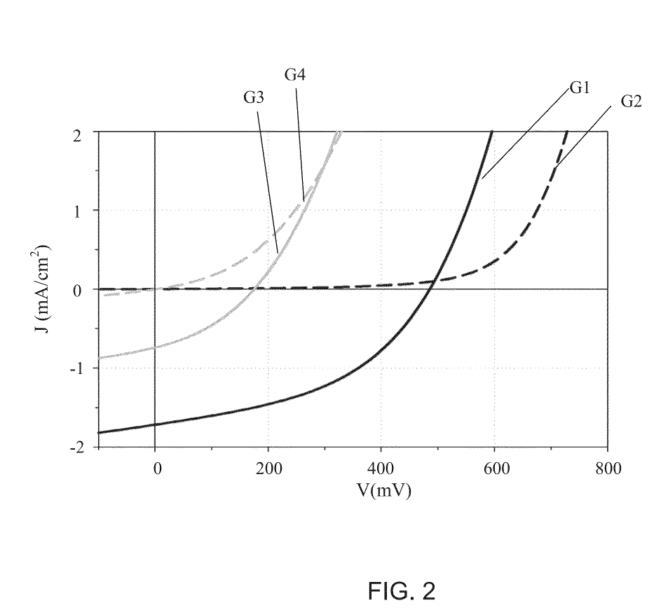

Reference is made to FIG. 2, showing the performance of the surface treated solar cells (graphs G₁, G₂) and untreated (conventional) ZnO|CdS|CuSCN solar cells (graphs G₃, G₄). This figure shows J-V curves for the solar cells in the dark (G₂, G₄) and under 1 sun illumination conditions (G₁, G₃). The effect of sulfide treatment on the performance of the cell is very pronounced from these graphs.

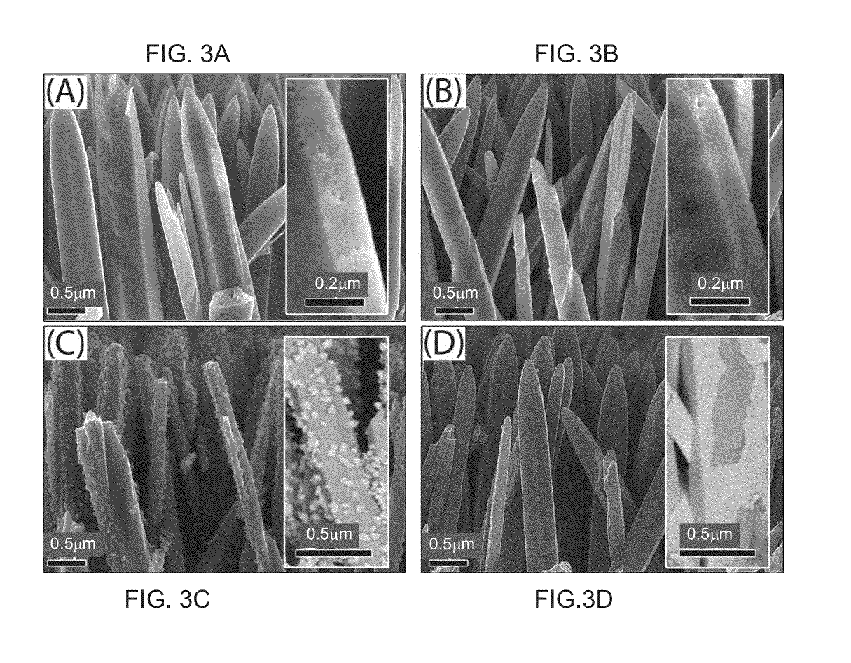

Referring to FIGS. 3A-3D, there are exemplified sequential steps in a method of the present invention for use in manufacture of a semiconductor device, especially a device utilizing a nanoporous semiconductor electrode, such as ZnO nanorod electrode, as typically suitable for use in semiconductor photovoltaic cells, compared to the conventional technique. The figures show scanning electron microscope (SEM) images of structures at the sequential steps of the method. FIG. 3A shows the SEM image of nanorods of ZnO layer (on a substrate, which is not shown here) having well-defined side faces with a rather smooth surface. The ZnO layer preparation may include addition of a small amount of antimony salt to the ZnO deposition solution.

FIG. 3B shows the results of the ZnO layer treatment a Na₂S solution, which converts the ZnO nanorod surface to ZnS, according to the invention. FIGS. 3C and 3D shows the SEM image corresponding to the (ZnO+CdS) structures obtained without and with the surface treatment, respectively, where CdS is deposited from an ethylenediamine/thiourea bath.

Thus, attempts to grow CdS on ZnO by a thiourea-based bath for CdS (the most common type used for this technique) resulted in clustering of the CdS and poor coverage of the ZnO (as seen in FIG. 3C). If, however, the ZnO is treated with a Na₂S solution, which converts the ZnO nanorod surface to ZnS (FIG. 3B), a much more even and conformal to coating by the CdS is obtained (FIG. 3D). It should be noted that the inset of FIG. 3D is deliberately chosen to show a nanorod where part of the CdS had peeled off (probably due to the preparation of the cross-section sample); this is in order to see the different contrast between the CdS and the ZnO. All the insets in the figures show backscattered SEM images which contrasts the Zn-containing part (dark contrast) with the Cd-containing part (light contrast). Thus the light parts are CdS while the dark parts are ZnO or ZnO/ZnS.

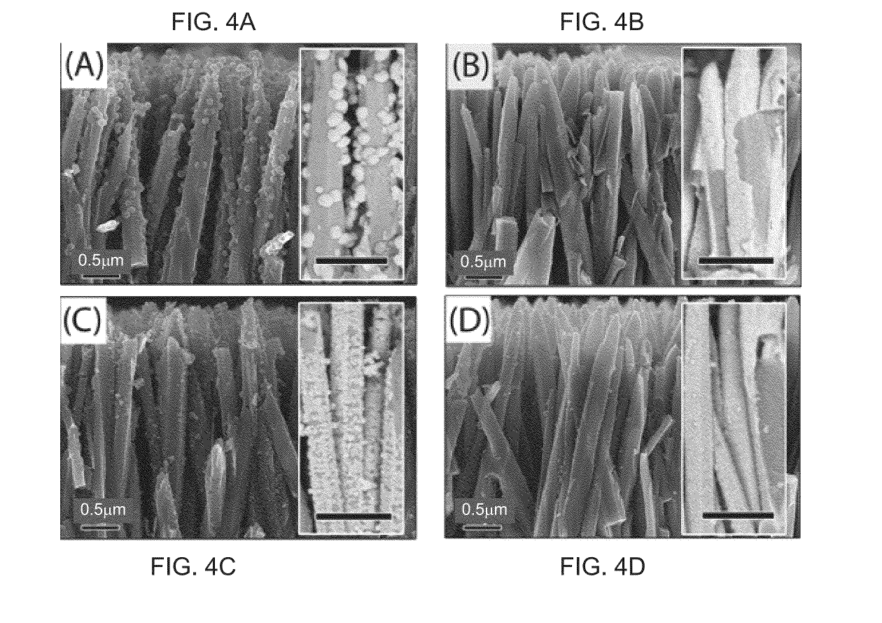

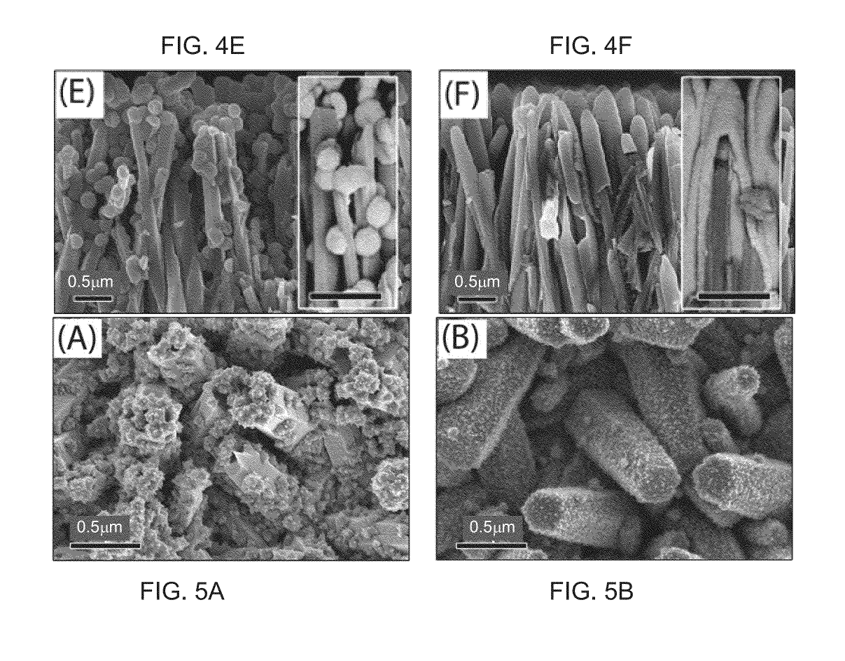

Reference is now made to FIGS. 4A to 4F showing the effect of sulfide treatment on ZnO surface coverage by two different metal chalcogenides (each constituting a semiconductor layer). These figures exemplify the CdS deposition from ammonia/thiourea bath (FIGS. 4A and 4B), CdS deposition from a thioacetatnide bath (FIGS. 4C and 4D) and CBD of CdSe (FIGS. 4E and 5F) for untreated ZnO (FIGS. 4A. 4C and 4E) and sulfide-treated ZnO (FIGS. 4B, 4D and 4F). Scale bars for the insets are all 0.5 μm.

The structure of the deposited CdS coating layer is affected by the deposition technique used. Deposition from a more commonly-used bath (ammonia-complexed instead of ethylenediamine), as shown in FIGS. 4A, 4B, has the same general features as in FIGS. 3C and 3D, meaning poor coverage on untreated ZnO and excellent coverage on the treated ZnO. Deposition of CdS on ZnO from a slightly acidic thioacetarnide bath has been described with good coverage found [7]. The inventors have experimentally shown that although this bath improves coverage on untreated ZnO as compared to the alkaline baths, much better uniformity was obtained from the same bath when the ZnO was Na₂S treated (FIG. 4D).

It should be noted that the effect of the ZnO treatment is not limited to CdS deposition. CBD of CdSe shows the same behavior, possibly even to a higher degree, with extensive clustering and poor coverage for the untreated ZnO, as seen in FIG. 4E, and very uniform coating for the treated ZnO as seen in FIG. 4F.

The inventors also investigated the effect of the sulfide treatment on ZnO prepared by a different method: using electrodeposited ZnO for this purpose. FIGS. 5A and 5B show CdS deposited by CBD on untreated (FIG. 5A) ZnO and on treated electrodeposited ZnO (FIG. 5B). In this method, again, the effect of the treatment on the coverage of the ZnO is very pronounced.

The treatment time of the ZnO layer by Na₂S solution is not critical. Good ZnS coverage is obtained after 30 seconds of treatment. However, the longer the surface treatment is, the thicker the ZnS layer. The thickness of the ZnS layer can be important for other purposes, for example. ZnS, has a high bandgap and low electron affinity (therefore high-lying conduction band) and therefore might be a good buffer layer [11,12] for solar cells using ZnO. Estimation of the effective ZnS thickness as a function of treatment time was made from a combination of XPS elemental analyses and SEM images. The Table below shows the XPS-derived average thickness values of the ZnS layer:

| Time | Thickness |
|---|---|
| [min] | [Å] |
| 0.5 | 3.4 |
| 1 | 4.0 |
| 2 | 5.2 |
| 5 | 8.2 |
| 10 | 12.3 |
| 20 | 19.5 |

These thickness values of the ZnS layer were calculated using the following expression (suited for a planar, uniform coating):

d=λ·ln(1+I_{ZnS}/I_{ZnO})

where d is the thickness of the ZnS layer, λ is the photoelectron inelastic mean free path (chosen to be 2.5 nm), and I_{ZnS} and I_{ZnO} are the intensities measured for ZnS and ZnO, respectively.

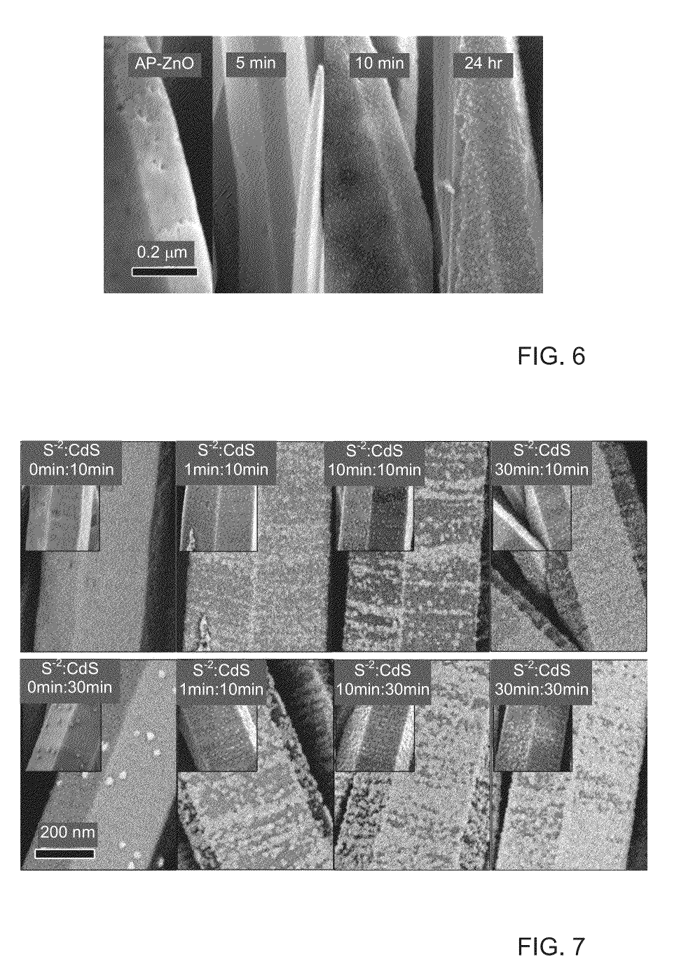

FIG. 6 shows the development of the ZnS film on top of ZnO nanorods for different treatment durations. Long surface treatment results in roughening of the ZnS film which is seen in FIG. 6, most left sample. The growth of the ZnS layer is close to linear with the surface treatment time up to about 20 min, and then slows down considerably.

FIG. 7 shows a set of backscattered SEM images with insets of secondary electron images showing deposition of CdS on treated and untreated ZnO for varying time durations. Generally, such duration may be of at least a few seconds, e.g. 10 seconds. The images from the top row left to right correspond to deposition of CdS for 10 minutes on ZnO after sulfide treatment times of 0, 1, 10 and 30 minutes, respectively. The bottom set of images show deposition of CdS for 30 minutes on ZnO treated for the same durations. Standard time duration for CdS deposition is about 150 minutes.

It is shown in FIG. 7 top left, and bottom left images that in the absence of any treatment, no CdS deposit is seen after 10 minutes, and 30 minutes after the deposition starts, only very isolated deposits are found. However, the use of 0.5 or preferably 1 minute of surface treatment according to the present invention is enough to improve the CdS coating drastically for both CdS deposition times. Longer surface treatment times further improve the CdS coating on the ZnO.

Sulfidation, the surface treatment applied on ZnO layer according to the present invention, is most rapidly carried out by a sulfide solution. Other sulfiding agents have the same effect but somewhat slower. A solution of 0.1 M Na₂S provide good coverage of the ZnO layer after 30 seconds. However, with 0.1 M solution of thioacetarnide, 40 minutes are required for a comparable effect. Use of thiourea solution of 1 M concentration will give a much lesser effect even after 40 minutes of treatment. These time durations are affected by the pH of the solution used.

For a typical surface treatment, ZnO films are immersed in a solution of 0.1 M Na₂S at room temperature for a certain time period. The concentration of Na₂S is not critical: the ZnO thickness is determined by a combination of Na₂S concentration and treatment time. Other solutions can be used, for example: 0.1 M ammonium sulfide, 0.1 M thioacetamide or 1 M thiourea. After the surface treatment, the surface is rinsed thoroughly with deionized water,

A layer of CdS or CdSe is deposited on top of the treated ZnO using CBD and a layer of hole-conductor, for example CuSCN, followed by an electrical contact (typically gold), are deposited on the semiconductor light absorbing layer.

The surface treatment process is at least partially reversible. When ZnO rods are treated with Na₂S and then annealed in air at 350° C., the rods are (rather uniformly) covered with small particles, presumably due to partial (back) oxidation and slight roughening of the to sulfided surface. Nonetheless, after 30 min of annealing, the surface coverage by CBD CdS is better than without the sulfide treatment (results not shown), although not as good as unannealed, sulfided ZnO. We also note that the effect did not result from simply cleaning of the ZnO surface by the basic sulfide solution. Treating the ZnO in KOH solution (up to 0.5 M) instead of Na₂S, which is expected to etch the ZnO, was not found to improve the surface coverage by CdS.

In the above-described example, the surface treatment is carried out from an alkaline solution. It should, however, be noted that a similar sulfide treatment may be carried out from a neutral or slightly acid solution. Generally, the required reaction may be obtained in the gas phase. The latter option might be more practical if the rest of the processes are also not solution processes but gas-phase/vacuum ones.

Besides the better coverage of ZnO with the absorber, there are two other factors that can be favorable for photovoltaic cells. These factors include that related to the role of the dense ZnO layer under the ZnO nanorods. This dense underlayer is necessary for both ZnO and TiO₂ based ETA cells to prevent shorting between the conducting glass and the solid hole-conductor. Such a dense underlayer may be formed in situ during deposition of ZnO [12]. However, this apparently dense layer is usually not good enough to prevent electrical shorting, even though it appears to be structurally dense under SEM imaging; this is probably due to very small cracks or pinholes in this dense layer. The sulfide treatment allows coverage of these defects by the CBD absorber, in contrast to the poor coverage of untreated ZnO; this can therefore block these defects and thus suppress shorting. This factor can explain the experimental results that cells made with untreated ZnO vary widely in performance, particularly in V_{OC} which will be most strongly affected by shorting, while cells made with treated ZnO are much more reproducible with a much narrower spread in performance, particularly in V_{OC}. Another factor is associated with the action of a thin ZnS film as a buffer layer. Such a buffer layer may effect reduction of recombination of electrons in the ZnO with holes in the absorber, or hole conductor by increasing electron hole separation and/or introduction of a potential barrier.

As indicated above, the present invention can be used in SSSCs (as exemplified above), and also in dye sensitized solar cells (DSSC), where instead of an absorbing to semiconductor, a molecular dye is adsorbed onto the porous oxide (often with a liquid electrolyte instead of a solid hole conductor). Such a DSSC using ZnO with surface treatment resulting in ZnS buffer between the ZnO and molecular dye structure might allow for replacing TiO₂ by ZnO.

A detailed description of an experimental deposition of solar cells according to the present invention is presented. It should be noted that this is anon,limiting example and is presented here in order to provide the skilled reader a better understanding of an embodiment of the present invention.

ZnO Film Deposition

The films were deposited on fluorine-doped tin oxide glass (FTO), or on soda lime glass microscope slides substrates. The substrates were cleaned by sonication in Alconox detergent solution for several minutes and thoroughly rinsed with Millipore deionized water.

The ZnO nanorod films were deposited mainly by chemical bath deposition (CBD) from an ammonia-based bath on KMnO₄-activated substrates [13]. For the surface activation, the substrates were immersed in closed vials containing 20 ml of 0.5 mM freshly prepared KMnO₄ solution with two or three drops of n-butanol. The vials were then placed in a pre-heated bath (90° [) for 30 minutes. To remove loosely-adhering Mn—O species the activated substrates were very extensively rinsed with deionized water (see ref. [13] for further details of the activation).

ZnO nanowire arrays were deposited on the activated substrates from deposition solutions containing 0.1M Zn(CH₃COO)₂, 1.7 M (10% v/v) ethanolamine and 0.6 M ammonium hydroxide. Each substrate was immersed tilted in the deposition solution in a closed vial and heated to 90° C. in a pre-heated bath for 45 min. After deposition, the films were rinsed with distilled water and dried in a flow of N₂.

In specified experiments, ZnO was electrochemically (cathodically) deposited on FTO glass from a solution of 0.05M zinc nitrate, at 70° C. A standard three electrode setup was used with a Ag/AgCl reference electrode and a Pt foil counter electrode. A potential of −0.9V and a typical deposition duration of 90 min was used.

ZnO Surface Treatment

For the typical surface treatment, ZnO films were immersed in a solution of 0.1 M Na₂S at room temperature for specific durations. In some cases, the ZnO was treated with solutions of: 0.1 M ammonium sulfide; 0.1 M potassium hydroxide; 0.1 M thioacetamide (40 min); or 1 M thiourea (40 min). After treatment, the samples were rinsed thoroughly with deionized water.

CWS Deposition

CdS was deposited by three different chemical bath deposition solutions:

Thiourea/ethylenediamine bath—0.025 M CdAc₂, 0.1 M ethylenediamine and 0.1 M thiourea at room temperature for 30-180 minutes. This was the mostly-used standard method.

Thiourea/ammonia bath—0.002 M CdSO₄, 0.01 M thiourea and 1 M ammonia. The solution was heated up to 60° C. for 100 minutes [6].

Thioacetamide bath—0.01 M Cd(NO₃)₂ and 0.01 M thioacetamide at room temperature for 40 minutes [7].

After CdS deposition the samples were rinsed with deionized water and dried in a N₂ flow.

CdSe Deposition

CdSe deposition was carried out by CBD. Stock solutions of 0.5M CdSO₄, 0.7M N(CH₂COOK)₃ (NTA) and 0.2M Na₂SeSO₃ (prepared by stirring 0.2M elemental Se with 0.5M Na₂SO₃ for ˜6-8 hr at 70° C.) were mixed to give a final solution composition of 80:80:160 mM Cd:Na₂SeSO₃:NTA, respectively. The pH was adjusted to 8.5 with KOH prior to addition of selenosulfate, and the final pH was 10.3. The samples were placed in a stirred water bath at 80° C. for 30 min and subsequently were rinsed with deionized water and dried in a N₂ flow.

CuSCAT Deposition and Solar Cell Fabrication

In this embodiment, to complete the photovoltaic device, a CuSCN hole conductor layer and gold contact were deposited on the samples, for example using the technique described before in [14] It should be noted that the use of hole conductor may be eliminated, by using the light absorbing semiconductor acting as a hole conductor, as described above with reference to FIG. 1B.

A saturated solution of CuSCN in dipropyl sulfide was prepared in advance by stirring the solution overnight and allowing it to settle for several days. This solution was diluted with dipropyl sulfide in 1:1 ratio to form 0.16M CuSCN solution concentration just before use. The samples were dipped in an aqueous solution of 0.5M LiSCN for 5 minutes at room temperature and the excess solution was gently-wiped with a tissue from the surface. The samples were then heated up on a hot plate to 65-75° C. and kept at this temperature during the deposition. CuSCN deposition was carried out in a home made apparatus using a movable syringe needle, sealed at the end and with four 0.3 mm diameter holes, spaced 3 mm apart drilled in the side of the needle. Typically 0.3-0.4 mL of solution was used for a sample area of 3 cm², resulting in a CuSCN layer 1-2 μm thick above the ZnO nanorods thus preventing contact between ZnO and the Au back contact. Gold contacts 60 nm thick were deposited on top of the CuSCN layer by electron beam evaporation.

Film and Cell Characterization

The morphology of the samples was observed by a SEM; Leo Ultra 55 scann electron microscope, in most cases using 2 kV accelerating voltage.

XPS measurements were carried out on a Kratos AXIS ULTRA system using a monocromatized Al Kα X-ray source at 75 W and detection pass energies ranging between 20 and 80 eV.

The photovoltaic response of the cells was measured using a white-light LED lamp calibrated to give the same short circuit current as natural sunlight, and normalized to full sun (100 mW·cm⁻²) using an Eppley pyranometer to measure the sunlight. Current-voltage (I-V) measurements were made using a Keithley 230 programmable voltage source and a Keithley 2000 multimeter. A defined area of 0.91 cm² was scribed around the gold contact to delineate the cell size.

Thus, the present invention provides for a novel method of manufacturing a semiconductor device, particularly an electromagnetic energy converter. This technique utilizes surface treatment of a ZnO porous layer to produce a ZnS film thereon (at room to temperature), prior to depositing an active material composition structure (light absorbing semiconductor structure or molecular dye structure), which thus becomes deposited on the ZnS film. This treatment greatly improves the performance of the semiconductor device, e.g. nanoporous ZnO/CdS solar cells.

Those skilled in the art will readily appreciate that various modifications and changes can be applied to the embodiments of the invention as hereinbefore described without departing from its scope defined in and by the appended claims.

1. A method for use in manufacture of a semiconductor device, the method comprising:
providing a structure comprising a ZnO layer;
applying a surface treatment to said structure for a certain time period to form a layer of ZnS on said ZnO layer; and
depositing an active layer structure on said ZnS layer, thereby providing substantially even coating of the ZnO layer by said active layer structure, wherein the active layer structure comprises at least one of the following: (a) a semiconductor layer structure, and (b) a molecular dye structure.

2. (canceled)

3. A method according to claim 1, wherein said active layer structure comprises the semiconductor layer structure comprising a light absorbing semiconductor.

4. A method according to claim 1, wherein said active layer structure comprises the molecular dye structure comprising a light absorbing molecular dye structure.

5. A method according to claim 1, comprising a substrate carrying the ZnO layer on its surface.

6. A method according to claim 5, characterized by at least one of the following: (i) said substrate is electrically conducting; (ii) said substrate is optically transparent.

7. (canceled)

8. A method according to claim 1, wherein said surface treatment comprises immersing said structure comprising the ZnO layer in a solution containing sulfide ions.

9. A method according to claim 1, wherein said certain time period is at least a few seconds.

10. A method according to claim 1, wherein said device comprises at least one photovoltaic cell.

11. A method according to claim 10, wherein said active structure comprises the semiconductor layer structure comprising at least one light absorbing material.

12. A method according to claim 1, wherein said semiconductor layer structure contains at least one metal chalcogenide.

13. A method according to claim 1, wherein said surface treatment is carried out under room temperature conditions.

14. A method according to claim 1, wherein said treatment utilizes a material conversion from an alkaline solution.

15. A method according to claim 1, wherein said treatment utilizes a material conversion from a neutral or slightly acid solution.

16. A method according to claim 1, wherein said treatment utilizes a material conversion in a gas phase.

17. A method according to claim 2, wherein said depositing of the semiconductor layer structure on said ZnS layer comprises depositing a layer of a semiconductor substance and then depositing a hole conducting layer onto said semiconducting layer.

18. A method according to claim 17, wherein said hole conducting layer comprises CuSCN.

19. (canceled)

20. A method for use in manufacture of an electrode arrangement for a photovoltaic cell, the method comprising:
providing a structure formed by a ZnO layer on an electrically conducting and optically transparent substrate;
applying a surface treatment to said structure for a certain time period to form a layer of ZnS on said ZnO layer;
depositing an active structure on said ZnS later, said active structure comprising at least one of the following: (a) a semiconductor layer structure comprising a light absorbing semiconductor, and (b) a molecular dye structure.

21. A method according to claim 20 wherein said semiconductor light absorber structure comprises at least one metal chalcogenide.

22. A semiconductor device comprising: an electrode structure comprising a ZnO porous layer, a ZnS layer on said ZnO layer, and an active structure on top of the ZnS layer, said active structure comprising at least one of the following: (a) a semiconductor layer structure, and (b) a molecular dye structure.

23. A semiconductor device according to claim 22, wherein said active structure comprises the semiconductor layer structure characterized by at least one of the following: (1) the semiconductor layer structure is a single- or two-layer structure; and (2) the semiconductor layer structure is configured as a light absorber, the device being thereby operable as a photovoltaic cell.

24. (canceled)

25. A semiconductor device according to claim 22, wherein said active structure comprises the semiconductor layer structure comprising a semiconductor light absorbing layer on top of said ZnS layer, the device being thereby operable as a photovoltaic cell.

26. A semiconductor device according to claim 22, wherein said active structure comprises the semiconductor layer structure comprising a semiconductor light absorbing layer on top of said ZnS layer, and a hole conducting layer on top of the semiconductor light absorbing layer, the device being thereby operable as a photovoltaic cell.

27. A semiconductor device of claim 22, configured and operable as a photovoltaic cell, wherein the layer of ZnS is located in between the ZnO layer and the active semiconductor layer structure comprising a light absorbing semiconductor.

28. A semiconductor device of claim 22, configured and operable as a photovoltaic cell wherein the molecular light absorbing dye is absorbed onto the treated ZnO layer.
